(19) United States
(12) Patent Application Publication
(10) Pub. No.: US 2026/0047402 A1
(43) Pub. Date: Feb. 12, 2026

(54) SEMICONDUCTOR STRUCTURE AND METHOD OF FABRICATING THE SAME

(71) Applicant: Fujian Jinhua Integrated Circuit Co., Ltd., Quanzhou City (CN)

(72) Inventors: Yingxiong Guo, Quanzhou City (CN); Wenzhang Li, Quanzhou City (CN)

(73) Assignee: Fujian Jinhua Integrated Circuit Co., Ltd., Quanzhou City (CN)

(21) Appl. No.: 19/043,506

(22) Filed: Feb. 2, 2025

(30) Foreign Application Priority Data
Aug. 8, 2024 (CN) 202411087575.1

(51) Int. Cl. H01L 21/027; G03F 1/36; H01L 21/033; H01L 21/311

(52) U.S. Cl. CPC H01L 21/0274; G03F 1/36; H01L 21/0337; H01L 21/31144

(57) ABSTRACT

The present disclosure provides a semiconductor structure and a method of fabricating the same, the semiconductor structure includes a substrate and a target layer. The target layer is disposed on the substrate and includes a target boundary and a plurality of target patterns. The target patterns are disposed within the target boundary, and arranged in a first direction and a second direction which are not perpendicular with each other, into an array. The target patterns include a plurality of odd columns and a plurality of even columns in a vertical direction, the target boundary includes a first arc edge and a second arc edge being protruded toward the vertical direction, and a central point of the first arc edge and a central point of the second arc edge are not on a same plane in a horizontal direction.

### CROSS REFERENCE TO RELATED APPLICATION

This application claims the benefit of Chinese Patent Application No. 202411087575.1 filed on Aug. 8, 2024, which is incorporated herein by reference.

### BACKGROUND OF THE INVENTION

### 1. Field of the Invention

The present disclosure generally relates to a semiconductor structure and a method of fabricating the same, and more particularly, to a semiconductor structure being fabricated through an optical proximity correction (OPC) technique, and a method of fabricating the same.

### 2. Description of the Prior Art

In the fabrication of integrated circuits (ICs), photolithography has been an essential technique. At present, the resolution required by photolithography at 32 nm node and below has exceeded the limit capability of the present mask aligner. Therefore, the double patterning technique (DPT), which can enlarge the minimum pattern distance on the present mask aligner, has become the solution for the line width between 32 nm to 22 nm. DPT technology includes decomposing a set of high-density circuit patterns into two or more sets of low-density circuit patterns; then fabricating photomasks having the sets of low-density circuit patterns respectively which can be used in the corresponding exposure and etching processes; and finally forming a merged pattern corresponding to the high-density patterns as originally required. However, because DPT must go through multiple exposure processes, overlay control and alignment have always been a concern of DPT, and the problem of overlay control and alignment is more prominent when the high-density circuit pattern is decomposed into two or more sets of circuit patterns with lower density. When DPT occurs overlay errors or inaccurate alignment occur in DPT, it will lead to disconnection or connection of circuit patterns, resulting in serious open circuit or short circuit. Therefore, there is still a need in the industry for a method of fabricating semiconductor structure that can overcome the above problems, and fabricate a more reliable semiconductor structure.

### SUMMARY OF THE INVENTION

An object of the present disclosure is to provide a method of fabricating a semiconductor structure, in which, a computing system is used to input a photomask pattern with a stepped surface, for improving the misalignment issue, space-wasting issue or patterning incomplete issue possibly caused by various arrangements or various sizes among different layout patterns, so that, a mask being outputted substantially will obtain more precise patterns and profiles thereby. Then, the mask will have improved quality and a semiconductor structure fabricated subsequently through the method of fabricating the semiconductor structure will therefore gain better reliability and performance.

An object of the present disclosure is to provide a semiconductor structure includes target patterns and a target boundary with an arc edge. Thus, the semiconductor structure enables to gain the improved quality and reliability to the target patterns and the target boundary, without performing any additional photolithography, so as to achieve better function and performance.

In order to achieve the above object, an embodiment of the present disclosure provides a method of fabricating a semiconductor structure including the following steps. A computing system is provided. A plurality of first photomask patterns is inputted, with the plurality of first photomask patterns being arranged into an array along a first direction and a second direction being not perpendicular to each other, and including a plurality of odd columns and a plurality of even columns in a vertical direction. A second photomask pattern is inputted to completely overlay each one of a portion of the plurality of first photomask patterns and to completely expose each one of another a portion of the plurality of first photomask patterns, wherein the second photomask pattern includes a stepped surface in a horizontal direction. The plurality of first photomask patterns and the second photomask pattern are sequentially outputted, to respectively form a first mask layer and a second mask layer on a target layer. An etching process is performed on the target layer through the first mask layer and the second mask layer, to form the semiconductor structure.

In order to achieve the above object, an embodiment of the present disclosure provides a method of fabricating a semiconductor structure including the following steps. A computing system is provided. A photomask pattern is inputted, with the photomask pattern including a first stepped surface and a second stepped surface respectively at two opposite sides thereof in the vertical direction. A decompose process is performed on the photomask pattern, decomposing the photomask pattern into a plurality of first stripe patterns and a plurality of second stripe patterns alternately arranged in a horizontal direction being perpendicular to the vertical direction. A trimming process is performed on the plurality of first stripe patterns and the plurality of second stripe patterns, expanding a width of each of the plurality of first stripe patterns and a width of each of the plurality of second stripe patterns in the horizontal direction, to form a plurality of first trimming patters and a plurality of second trimming patterns, wherein each of the plurality of first trimming patters overlaps an adjacent one of the plurality of second trimming patters. The plurality of first trimming patters and the plurality of second trimming patterns are merged, to form a merged photomask pattern. The merged photomask pattern is outputted, to form a mask layer on a target layer. An etching process is performed on the target layer through the mask layer, to form the semiconductor structure.

In order to achieve the above object, an embodiment of the present disclosure provides a semiconductor structure including a substrate and a target layer. The target layer is disposed on the substrate and includes a target boundary and a plurality of target patterns. The plurality of target patterns is disposed within the target boundary, the plurality of target patterns is arranged in a first direction and a second direction into an array and includes a plurality of odd columns and a plurality of even columns in a vertical direction, the target boundary includes a first arc edge and a second arc edge being protruded toward the vertical direction, and a central point of the first arc edge and a central point of the second arc edge are not on a same plane in a horizontal direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 9 are schematic diagrams illustrating a method of fabricating a semiconductor structure according to a first embodiment of the present disclosure, wherein:

FIG. 1 is a schematic flow diagram of the method of fabricating the semiconductor structure;

FIG. 2 is a schematic diagram of inputting a first photomask pattern and a second photomask pattern;

FIG. 3 is a schematic diagram of decomposing a second photomask pattern;

FIG. 4 is a schematic diagram of outputting a first photomask pattern;

FIG. 5 is a schematic diagram of forming a first mask layer;

FIG. 6 is a schematic top view diagram of forming a second mask layer;

FIG. 7 is a schematic cross-sectional diagram taken along the cross-line A-A′ in FIG. 6;

FIG. 8 is a schematic top view diagram of forming a semiconductor structure; and

FIG. 9 is a schematic cross-sectional diagram taken along the cross-line A-A′ in FIG. 8.

FIG. 10 to FIG. 12 are schematic diagrams illustrating a method of fabricating a semiconductor structure according to another embodiment of the present disclosure, wherein:

FIG. 10 is another schematic diagram of decomposing a second photomask pattern;

FIG. 11 is the other schematic diagram of decomposing a second photomask pattern; and

FIG. 12 is the other schematic diagram of decomposing a second photomask pattern.

FIG. 13 to FIG. 15 are schematic diagrams illustrating a method of fabricating a semiconductor structure according to a second embodiment of the present disclosure, wherein:

FIG. 13 is a schematic flow diagram of the method of fabricating the semiconductor structure;

FIG. 14 is a schematic diagram of inputting a photomask pattern; and

FIG. 15 is a schematic diagram of decomposing a photomask pattern.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

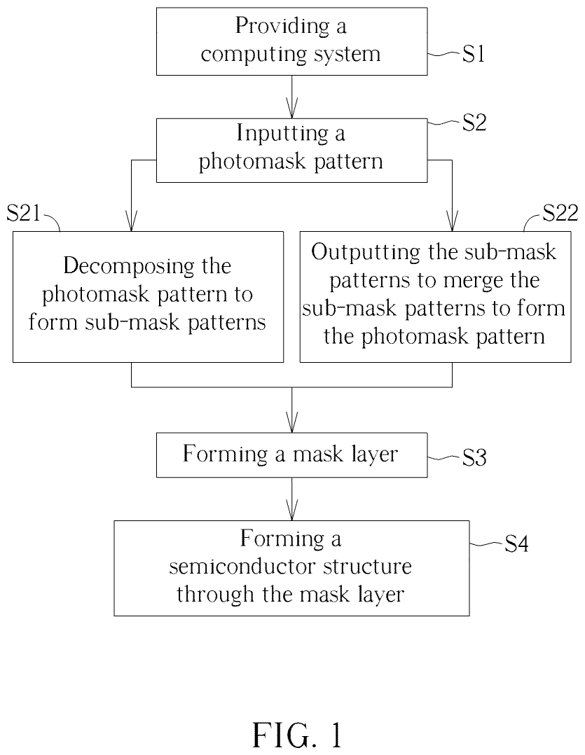

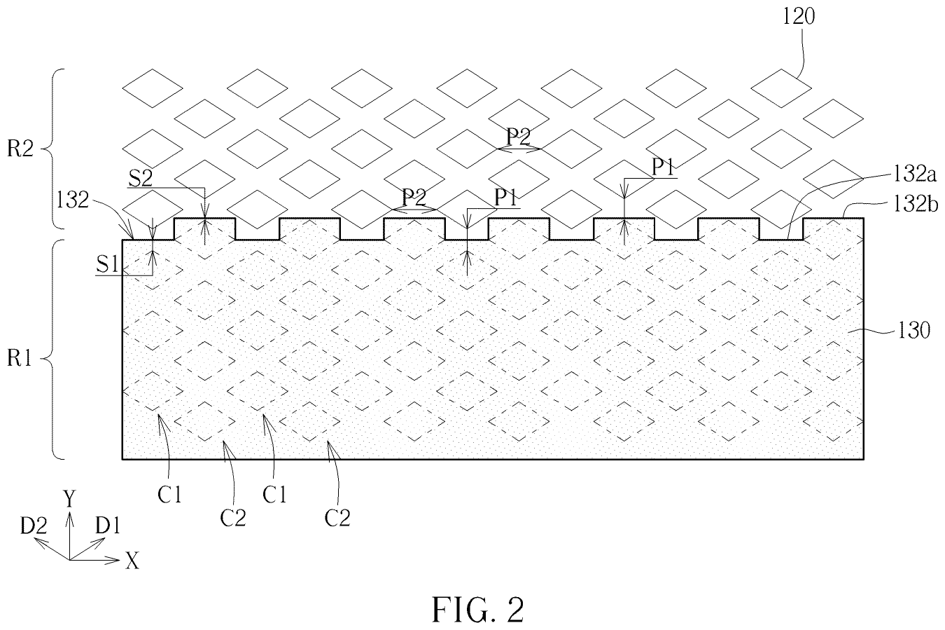

Please refer to FIG. 1 to FIG. 9, which are schematic diagrams illustrating a method of fabricating a semiconductor structure according to a first embodiment of the present disclosure. Firstly, as shown in FIG. 1 and FIG. 2, the method of fabricating a semiconductor structure in the present embodiment includes but not limited to the following steps. A computing system is provided (step S1), for example being a computer component (not shown in the drawings), and a photomask pattern is inputted through the computer component (step S2). The photomask pattern for example includes a plurality of first photomask patterns 120 and a second photomask pattern 130 as shown in FIG. 2, and the first photomask patterns 120 and the second photomask pattern 130 are sequentially inputted into the computer component in the present embodiment. Precisely speaking, as shown in FIG. 2, the first photomask patterns 120 are arranged for example in a first direction D1 and a second direction D2 being not perpendicular to each other into an array, with any two adjacent ones of the first photomask patterns 120 include the same pitch P1 therebetween in a vertical direction Y, and the same pitch P2 therebetween in a horizontal direction X, but not limited thereto. The array for example includes a plurality of odd columns C1 and a plurality of even columns C2 each arranged in the vertical direction Y. Any one of the first photomask patterns 120 arranged in one of the odd columns C1 is misaligned with a corresponding one of the first photomask patterns 120 arranged in one of the even columns C2, without being aligned with each other, and any one of the first photomask patterns 120 arranged in one of the odd columns C1 or in one of in the even columns C2 is aligned with a corresponding one of the first photomask patterns 120 arranged in another one of the odd columns C1 or in another one of the even columns C2, as shown in FIG. 2, but not limited thereto.

Further in view of FIG. 2, the second photomask pattern 130 overlays the first photomask patterns 120 and includes a stepped surface 132 in a horizontal direction X. Preferably, the second photomask pattern 130 completely overlaps a portion R1 of the first photomask patterns 120, with another portion R2 of the first photomask patterns 120 being exposed from the second photomask pattern 130. In other words, neither one of the first photomask patterns 120 is partially covered by nor partially exposed from the second photomask pattern 130. It is noted that, the stepped surface 132 of the second photomask pattern 130 further includes a plurality of first planes 132a and a plurality of second planes 132b alternately arranged with each other, with each of first planes 132a being not coplanar with each of the second planes 132b. A minimum distance S1 between any one of the first planes 132a to an adjacent one of the first photomask patterns 120 in the vertical direction Y, or a minimum distance S2 between any one of the second planes 132b to an adjacent one of the first photomask patterns 120 in the vertical direction Y are both preferably smaller than the pitch P1 of two adjacent ones of the first photomask patterns 120 in the vertical direction Y, so that, the stepped surface 132 is allowable to extend along the outline of the portion R1 of the first photomask patterns 120, without excessively overlaying any portion outside the region R1 of the first photomask patterns 120. In one embodiment the minimum distance S1 and the minimum distance S2 may be the same as each other or different from each other, and which is not limited by what is shown in FIG. 2.

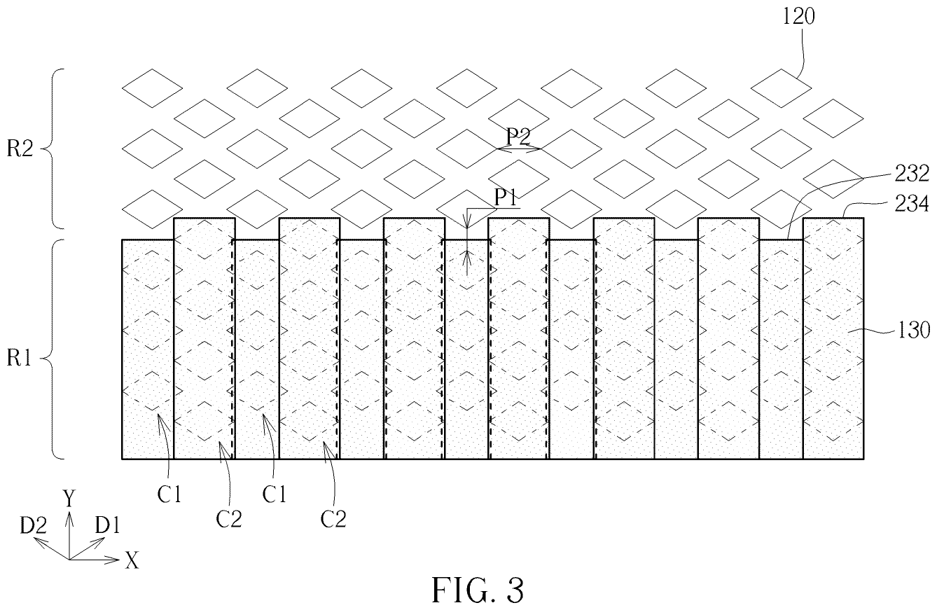

Next, as shown in FIG. 1 and FIG. 3, the photomask pattern is decomposed to generate at least one sub-mask pattern (step S21). Precisely speaking, the second photomask pattern 130 is decomposed to generate a plurality of sub-mask patterns with the sub-mask patterns being at least partially overlapped with each other. In one embodiment, the sub-mask patterns for example includes a plurality of first sub-mask patterns 232 and a plurality of second sub-mask patterns 234 as shown in FIG. 3, with a portion of the first sub-mask patterns 232 each overlaying an adjacent one of the second sub-mask patterns 234, and with another portion of the first sub-mask patterns 232 each only adjacent to an adjacent one of the second sub-mask patterns 234, but not limited thereto. The first sub-mask patterns 232 and the second sub-mask patterns 234 respectively includes a stripe-shaped pattern extending in the vertical direction Y, with a top surface of each of the first sub-mask patterns 232 being aligned with each first plane 132a of the stepped surface 132, and with a top surface of each of the second sub-mask patterns 234 being aligned with each second plane 132b of the stepped surface 132. Accordingly, the first sub-mask patterns 232 and the second sub-mask patterns 234 are alternately arranged in the horizontal direction X, respectively overlaying the first photomask patterns 120 arranged in the odd columns C1 and the first photomask patterns 120 arranged in the even columns C2.

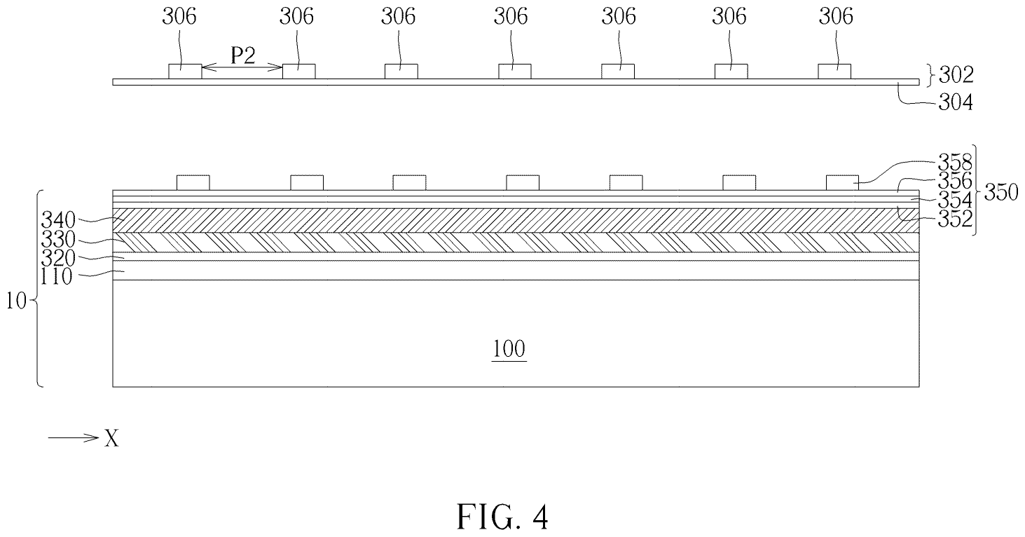

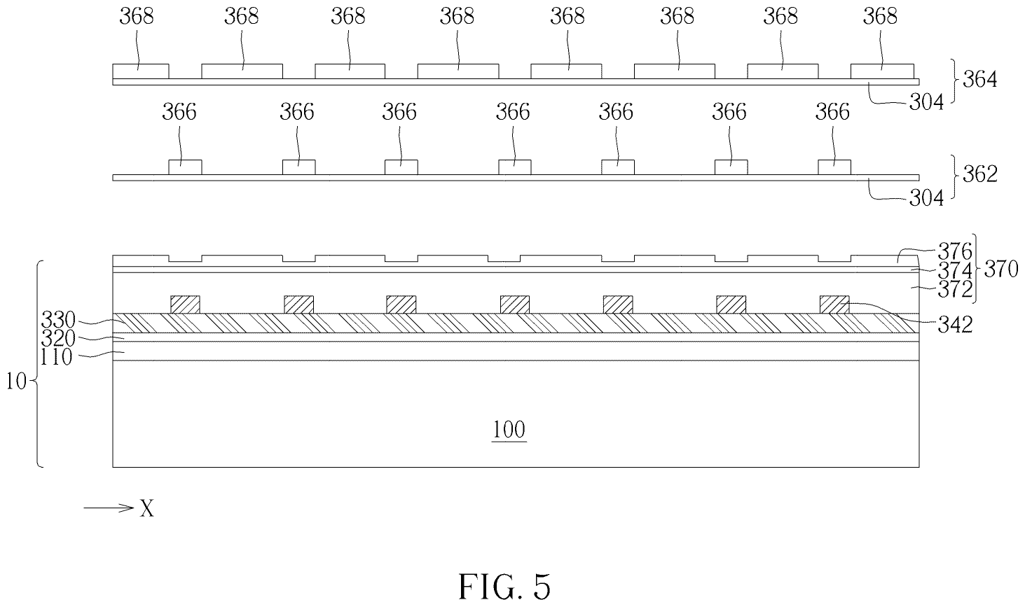

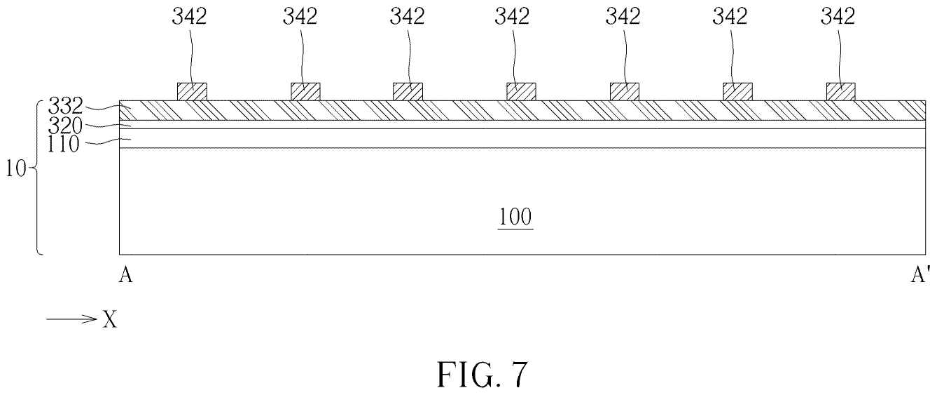

Next, as shown in FIG. 1, FIG. 3 and FIG. 7, a mask layer is formed (step S3). Firstly, as shown in FIG. 3 to FIG. 5, the first photomask patterns 120 as shown in FIG. 3 are outputted through the computer component, to form a first photoresist 302 as shown in FIG. 4, and a subsequent exposure process and a development process are performed on a semiconductor structure 10 according to the first photoresist 302, to finally form a first mask layer 342 as shown in FIG. 5. Precisely speaking, as shown in FIG. 4, the first photoresist 302 includes a substrate 304 for light transmission such as a transparent quartz substrate, and light shielding patterns 306 formed on the substrate 304, with each of the light shielding patterns 306 being corresponded to the each of the first photomask patterns 120 as shown in FIG. 3, and having the same pitch P2 in the horizontal direction X. On the other hand, the semiconductor structure 10 includes a substrate 100 such a silicon substrate or a silicon-on-insulator (SOI) substrate, and a target layer 110, a protection layer 320, a mask layer 330, a mask layer 340, and a first photoresist structure 350 stacked in sequence on the substrate 100. In one embodiment, the target layer 110 for example includes a conductive material being a low-resistant metal material like aluminum (Al), titanium (Ti), copper (Cu) or tungsten (W), or a dielectric material being silicon oxide, silicon nitride or silicon oxynitride, and the target layer 110 may be used in the subsequent process, being patterned into the requested pattern through a photolithography process. The protection layer 320 for example includes a dielectric material like silicon nitride, silicon oxide, silicon oxynitride, for protecting the target layer 110 underneath, and the mask layer 330 and the mask layer 340 for example include a suitable mask material like silicon oxide or amorphous silicon, for easily transferring the requested patterns in the subsequent processes, but not limited thereto.

As shown in FIG. 4, the first photoresist structure 350 precisely includes a photoresist bottom layer 352 (for example including a spin-on carbon (SOC) layer), a photoresist intermediate layer 354 (for example including silicon oxynitride), a bottom anti-reflective coating (BARC) layer 356, and a patterned photoresist layer 358 stacked from bottom to top. The patterned photoresist layer 358 has been patterned through performing an exposure process and a development process, with the light shielding patterns 306 being transferred thereon to obtain the corresponding patterns of the light shielding patterns 306. It is noted that, while the exposure process and a development process are carried out for transferring the light shielding patterns 306 into the patterned photoresist layer 358, the width or the pitch of the light shielding patterns 306 may be proportionally reduced, but not limited thereto. Then, an etching process is performed, to transfer the patterns of the patterned photoresist layer 358 into the mask layer 340 underneath, to form the first mask layer 342 as shown in FIG. 5, followed by completely removing the first photoresist structure 350.

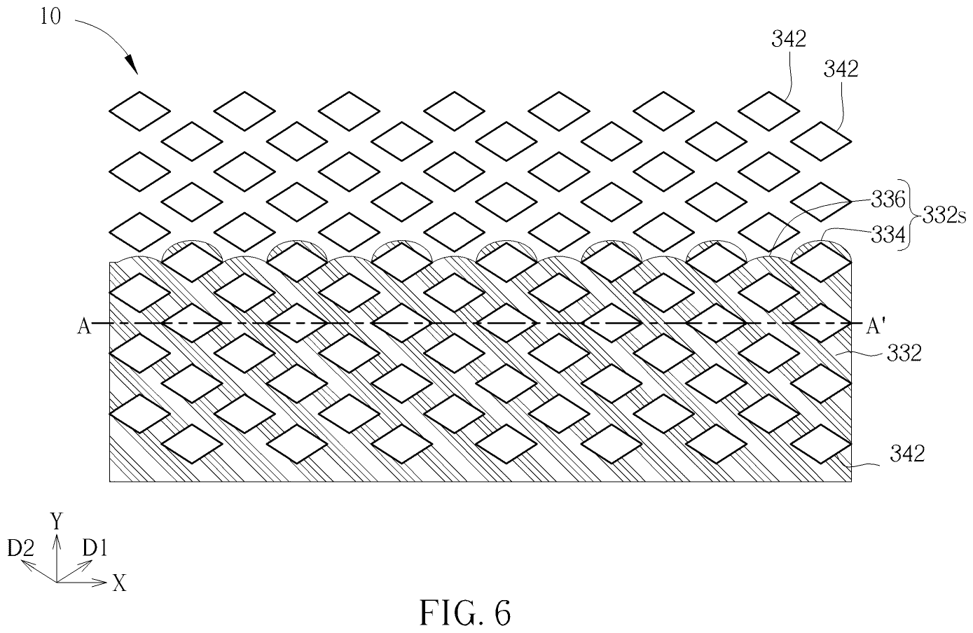

As shown in FIG. 3, FIG. 5, and FIG. 7, the first sub-mask patterns 232 and the second sub-mask patterns 234 decomposed from the second photomask pattern 130 as shown in FIG. 3, are sequentially outputted through the computer component, to form second photoresist layers 362, 364 as shown in FIG. 5, and a subsequent exposure process and a development process are performed on the semiconductor structure 10 according to the second photoresist layers 362, 364, to form a second mask layer 332 as shown in FIG. 6 and FIG. 7. Precisely speaking, as shown in FIG. 5, the second photoresist layers 362, 364 each also includes a substrate 304 for light transmission, and light shielding patterns 366, 368 formed on the substrate 304, with each of the light shielding patterns 366, 368 being corresponded to each of the first sub-mask patterns 232 and the second sub-mask patterns 234 as shown in FIG. 3. Then, a second photoresist structure 370 is formed on the substrate 100, and which precisely includes a photoresist bottom layer 372 (for example including an organic dielectric layer), a photoresist intermediate layer 374 (for example including silicon oxynitride), and a patterned photoresist layer 376 stacked from bottom to top. The patterned photoresist layer 376 has been patterned through performing an exposure process and a development process, with the light shielding patterns 366, 368 being transferred thereon to obtain the corresponding patterns of the light shielding patterns 366, 368. Then, an etching process is performed to transfer the patterns of the patterned photoresist layer 376 into the mask layer 330 underneath, to form the second mask layer 332 as shown in FIG. 6 and FIG. 7, followed by completely removing the second photoresist structure 370.

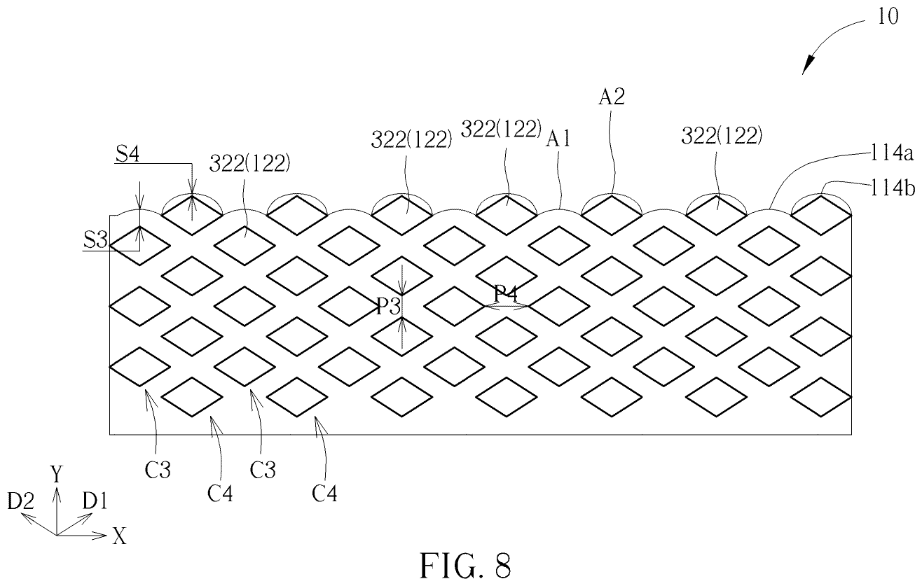

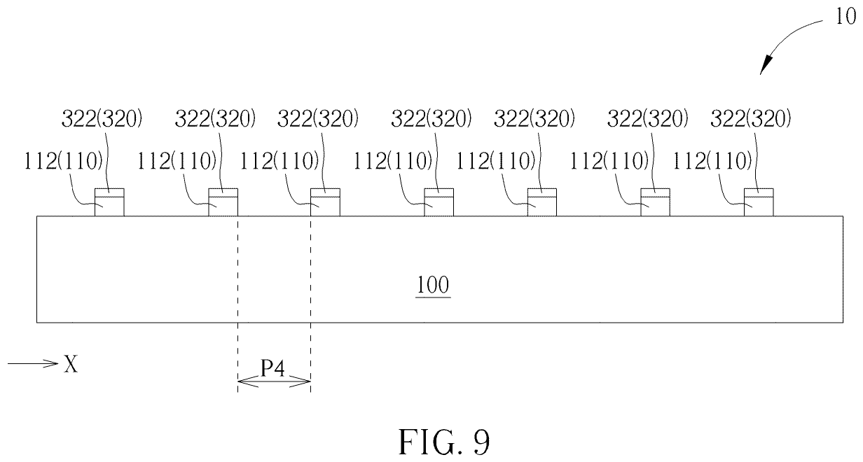

According to the optical proximity correction, when the exposure process and the development process are respectively performed through the second photoresist layers 362, 364, a plurality of patterns (not shown in the drawings) with arc edges is correspondingly generated on the patterned photoresist layer 376 as shown in FIG. 5. Then, while these patterns with arc edges are simultaneously transferred into the second mask layer 332, arc edges 332s as shown in FIG. 6 will be correspondingly formed on the second mask layer 332, including a plurality of first arc edges 334 and a plurality of second arc edges 336 respectively protruding toward the vertical direction Y. Following these, as shown in FIG. 1, FIG. 6 and FIG. 9, the semiconductor structure 10 is formed through a mask layer (step S4). As shown in FIG. 1, FIG. 6 and FIG. 9, an etching process is performed on the protection layer 320 and the target layer 110 underneath, through the first mask layer 342 and the second mask layer 332 as shown in FIG. 6 and FIG. 7, to transfer the patterns of the first mask layer 342 into the protection layer 320 and the target layer 110 to form a plurality of protection patterns 322 and a plurality of target patterns 112 underneath, as shown in FIG. 8 and FIG. 9, and also, to transfer the patterns of the second mask layer 332 into the protection layer 320 and the target layer 110 to define a target boundary 114 as shown in FIG. 8 on the target layer 110. Through these arrangements, the semiconductor structure 10 as shown in FIG. 8 and FIG. 9 is formed, and the first mask layer 342, the second mask layer 332, and the protection layer 320 are completely removed.

As shown in FIG. 8 and FIG. 9, the semiconductor structure 10 includes a plurality of target patterns 112 is arranged in the first direction D1 and the second direction D2 into an array, and two adjacent ones of the target patterns 112 include the same pitch P3, P4 both in the vertical direction Y and in the horizontal direction X, but not limited thereto. The target patterns 112 are further arranged in the vertical direction Y into a plurality of odd columns C3 and a plurality of even columns C4, with the odd columns C3 and the even columns C4 being alternately arranged with each other in the horizontal direction X. It is noted that, one of the target patterns 112 arranged in one of the odd columns C3 is misaligned with a corresponding one of the target patterns 112 arranged in one of the even columns C4 adjacent to the one of the odd columns C3, instead of being aligned with each other, and one of the target patterns 112 arranged in one of the odd columns C3 or one of the even columns C4 is aligned with a corresponding one of the target patterns 112 arranged in another one of the odd columns C3 or another one of the even columns C4, as shown in FIG. 8, but not limited thereto.

On the other hand, the target boundary 114 is for example extended along the outline of the target patterns 112, and further includes a plurality of first arc edges 114a and a plurality of second arc edges 114b respectively protruding toward the vertical direction Y. A central point A1 of the first arc edge 114a and a central point A2 of the second arc edge 114b are not on the same plane. It is noted that a minimum distance S3 from the central point A1 of the first arc edge 114a to a corresponding one of the target patterns 112 arranged in the odd columns C3 is less than the pitch P3, and a minimum distance S4 from the central point A2 of the second arc edge 114b to a corresponding one of the target patterns 112 arranged in the even columns C4 is less than the pitch P3. Then, the area outside the target pattern 112 will not be oversized, so as to improve the component arrangement on the semiconductor structure 10.

According to the method of fabricating the semiconductor structure of the present embodiment, the second photomask pattern with the stepped surface is inputted in the computing system, with the stepped surface being extending along the outline of the uneven layout on the first photomask patterns, so that the first photomask patterns within the corresponding region can be completely and effectively covered by the second photomask pattern, avoiding any incomplete covering or expanding covering of the first photomask patterns. Through these performances, the method of fabricating the semiconductor structure in the present embodiment enables to improve the misalignment issue, space-wasting issue or patterning incomplete issue possibly caused by various arrangements or various sizes among different layout patterns, so that, a mask being outputted substantially will obtain more precise patterns and profiles thereby. In addition, before outputting the first photomask patterns and the second photomask pattern, the second photomask pattern may be optionally decomposed into a plurality of sub-mask patterns being at least partially overlapped with each other, with the sub-mask patterns matching the uneven layout and the outline, such that, the quality of the mask being outputted substantially will be further improved, and the semiconductor structure being fabricated thereby will therefore gain better reliability and structure.

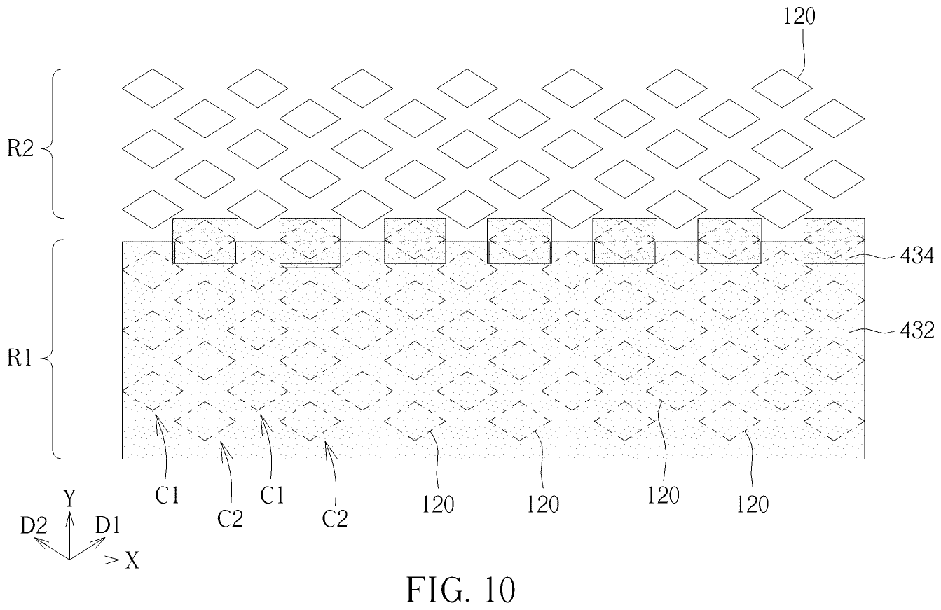

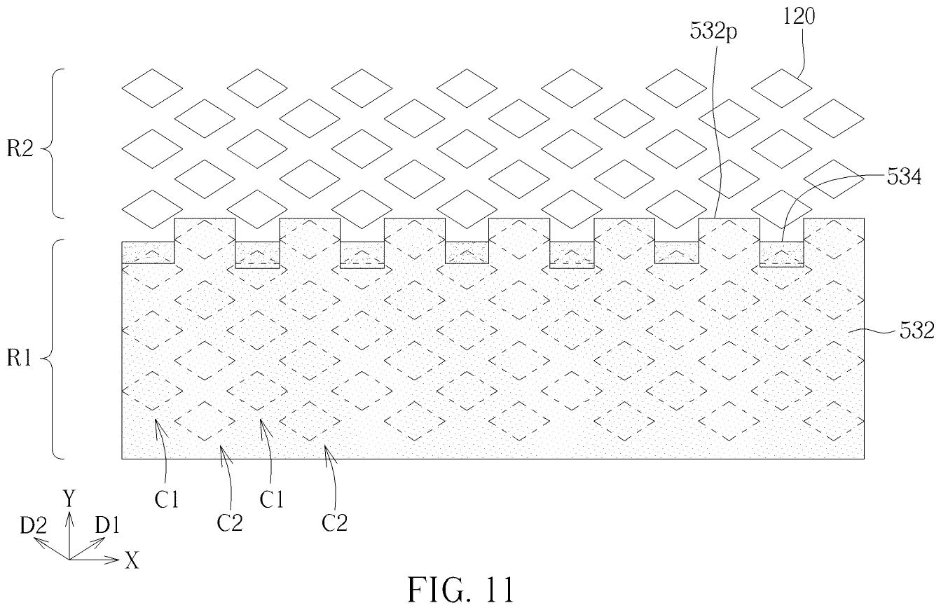

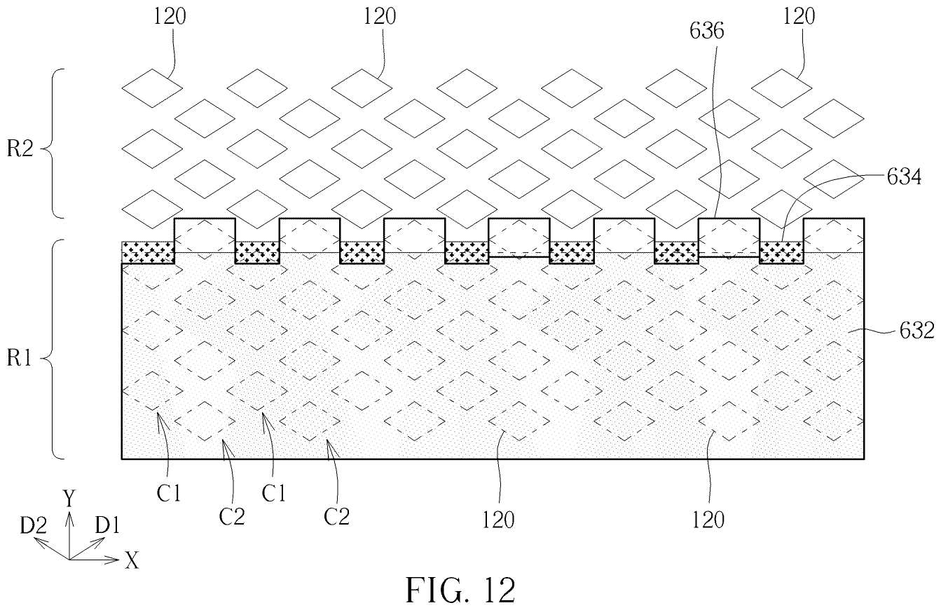

Thus, the method of fabricating the semiconductor structure of the present embodiment can be further in use on fabricating any suitable semiconductor device such as a memory device like a dynamic random-access memory (DRAM) device, for fabricating components or circuits with a relative higher integration, but not limited thereto. For example, the aforementioned first photomask patterns may be used to form a photomask of storage node plugs or storage node pads, while the aforementioned second photomask pattern may be used to form a photomask for defining the layout boundary of the storage node plugs or the storage node pads. People skilled in the art should fully understand that the practical arrangement and layout of the first photomask patterns, the practical profile of the stepped surface of the second photomask pattern, and/or the practical arrangement and layout of the sub-mask patterns are not limited to what are shown in the aforementioned drawings, and which can be further adjusted due to practical product requirements. In another embodiment, the sub-mask patterns may further include a first sub-mask pattern 432 and a plurality of second sub-mask patterns 434 as shown in FIG. 10, or include a first sub-mask pattern 532 and a plurality of second sub-mask patterns 534 as shown in FIG. 11, or include a first sub-mask pattern 632, a plurality of second sub-mask patterns 634, and a plurality of third sub-mask patterns 636, as shown in FIG. 12, but not limited thereto.

Precisely speaking, as shown in FIG. 10, the first sub-mask pattern 432 for example includes a rectangular shape, with the first sub-mask pattern 432 entirely overlaying the region R1 of the first photomask patterns 120, and with some of the first photomask patterns 120 arranged in the even columns C2 being partially exposed from the first sub-mask pattern 432. The second sub-mask patterns 434 are sequentially arranged in the horizontal direction X, and each partially overlaps the first sub-mask pattern 432. Accordingly, each of the second sub-mask patterns 434 will right overlay the first photomask patterns 120 which are arranged in the even columns C2 and are partially exposed from the first sub-mask pattern 432. That is, through the arrangement and combination between the first sub-mask pattern 432 and the second sub-mask patterns 434, the top surface of the first sub-mask pattern 432 and the top surfaces of the second sub-mask patterns 434 are allowable to be aligned with the first planes 132a and the second planes 132b of the stepped surface 132 as shown in FIG. 2, such that, the sub-mask pattern will therefore achieve the complete coverage of the region R1 of the photomask patterns 120.

On the other hand, as shown in FIG. 11, the first sub-mask pattern 532 for example includes a plurality of protrusions 532P extending toward the vertical direction Y, for completely overlaying all of the first photomask patterns 120 arranged in the even columns C2. The second sub-mask patterns 534 are sequentially arranged in the horizontal direction X, overlaying the first sub-mask patterns 532 respectively, and which are alternately arranged with the protrusions 532P of the first sub-mask pattern 532, for completely overlapping the first photomask patterns 120 being arranged in the odd columns C1 and exposed from the first sub-mask pattern 532. That is, through the arrangement and combination between the first sub-mask pattern 532 and the second sub-mask patterns 534, the top surface of the protrusions 532P of the first sub-mask pattern 532, and the top surface of the second sub-mask patterns 534 are allowable to be aligned with the first planes 132a and the second planes 132b of the stepped surface 132 as shown in FIG. 2, such that, the sub-mask pattern will therefore achieve the complete coverage of the region R1 of the photomask patterns 120.

On the other hand, as shown in FIG. 12, the first sub-mask pattern 632 for example includes a rectangular shape, with the first sub-mask pattern 632 entirely overlaying the region R1 of the first photomask patterns 120, and with some of the first photomask patterns 120 arranged in the odd columns C1 or in the even columns C2 being partially exposed from the first sub-mask pattern 632. The second sub-mask patterns 634 and the third sub-mask patterns 636 are alternately arranged and partially overlapped with the first sub-mask pattern 632, with each of the second sub-mask patterns 634 completely overlapping the first photomask patterns 120 arranged in the odd columns C1 and exposed from the first sub-mask pattern 632, and with the third sub-mask patterns 636 completely overlapping the first photomask patterns 120 arranged in the even columns C2 and exposed from the first sub-mask pattern 632. That is, through the arrangement and combination between the first sub-mask pattern 632, the second sub-mask patterns 634 and the third sub-mask patterns 636, the top surfaces of the second sub-mask patterns 634 and the top surfaces of the third sub-mask patterns 636 are allowable to be aligned with the first planes 132a and the second planes 132b of the stepped surface 132 as shown in FIG. 2, such that, the sub-mask pattern will therefore achieve the complete coverage of the region R1 of the photomask patterns 120.

Through these performances, while the second photomask pattern 130 as shown in FIG. 2 is outputted through the computer component, the second photomask pattern 130 will firstly be decomposed into the first sub-mask pattern 432 and the plurality of second sub-mask patterns 434 (as shown in FIG. 10), or the first sub-mask pattern 532 and the plurality of second sub-mask patterns 534 (as shown in FIG. 11), or the first sub-mask pattern 632, the plurality of second sub-mask patterns 634 and the plurality of third sub-mask patterns 636 (as shown in FIG. 12), followed by simultaneously outputted these sub-mask patterns to form a photoresist layer. Then a subsequent exposure process and a development process are performed to form the semiconductor structure 10 as shown in FIG. 8, through the photoresist layer.

People well known in the arts should easily realize the method of fabricating a semiconductor structure in the present disclosure is not limited to the aforementioned embodiment, and may further include other examples or variety, so as to meet the practical product requirements. In another embodiment, while the patterns are inputted, the first sub-mask pattern 232 and the plurality of second sub-mask patterns 234 as shown in FIG. 3, or the first sub-mask pattern 432 and the plurality of second sub-mask patterns 434 as shown in FIG. 10, or the first sub-mask pattern 532 and the plurality of second sub-mask patterns 534 as shown in FIG. 11, or the first sub-mask pattern 632, the plurality of second sub-mask patterns 634 and the plurality of third sub-mask patterns 636 as shown in FIG. 12, are previously inputted through the computer component, and a pattern merging process is then performed, merging the first sub-mask pattern 232 and the plurality of second sub-mask patterns 234 as shown in FIG. 3, or the first sub-mask pattern 432 and the plurality of second sub-mask patterns 434 as shown in FIG. 10, or the first sub-mask pattern 532 and the plurality of second sub-mask patterns 534 as shown in FIG. 11, or the first sub-mask pattern 632, the plurality of second sub-mask patterns 634 and the plurality of third sub-mask patterns 636 as shown in FIG. 12, to form a photomask pattern (step S21). Next, the photomask pattern is outputted through the computer component to form a photoresist layer. The following description will detail the different embodiments of a method of fabricating a semiconductor structure in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

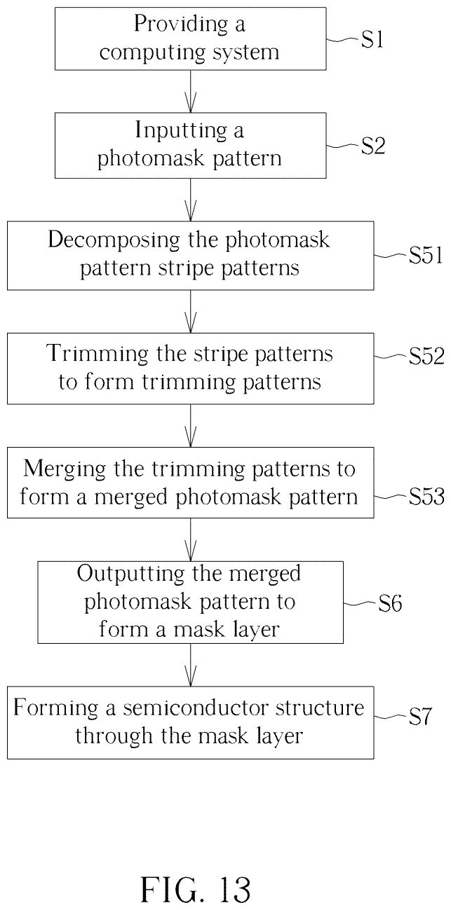

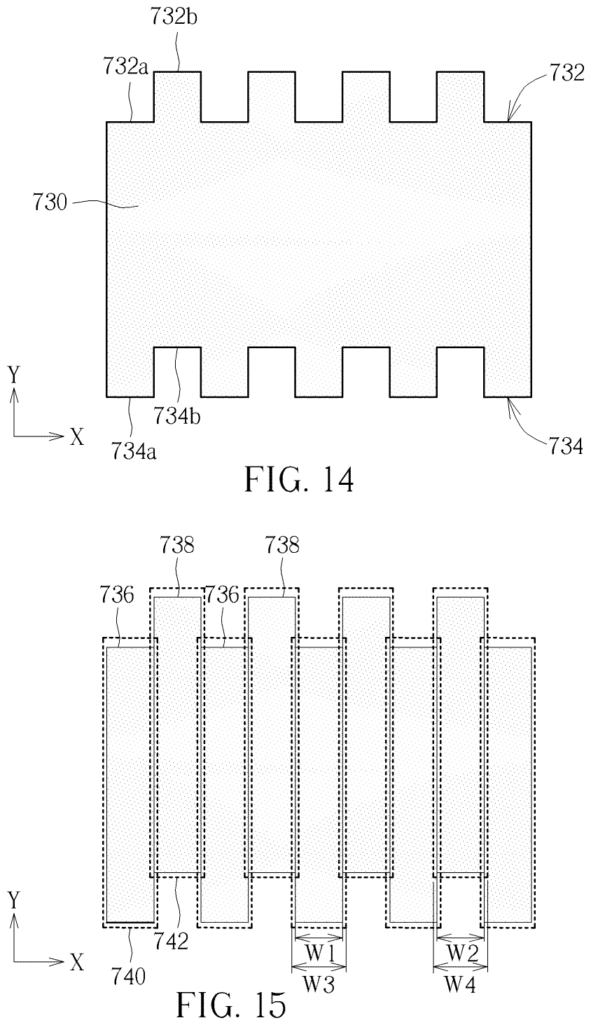

Please refer to FIG. 13 to FIG. 15, which are schematic diagrams illustrating a method of fabricating a semiconductor structure according to a second embodiment of the present disclosure. Firstly, as shown in FIG. 13 and FIG. 14, A computing system is provided (step S1), for example being a computer component (not shown in the drawings), and a photomask pattern is inputted through the computer component (step S2). Precisely speaking, the photomask pattern 730 includes a first stepped surface 732 and a second stepped surface 734 at two opposite sides thereof in the vertical direction Y, with the first stepped surface 732 and the second stepped surface 734 respectively including a plurality of first planes 732a/734a and a plurality of second planes 732b/374b alternately arranged with each other, for effectively covering and corresponding to patterns or region with various layouts or arrangements. That is, although the first photomask patterns 120 of the aforementioned embodiment, or other similar patterns in another arrangement or layout, have been omitted in the drawings of the present embodiment, people skilled in the art should fully realize that the photomask pattern 730 is inputted into the computer component according to the fabricating requirements of the practical structure, so as to be in correspondence with the aforementioned pattern and the region, and to effectively covering or overlapping the aforementioned pattern and the region thereby.

As shown in FIG. 13 to FIG. 15, the mask pattern is decomposed into stripe patterns (step S51). Precisely speaking, the photomask pattern 730 is decomposed into a plurality of first stripe patterns 736 and a plurality of second stripe patterns 738, respectively extending in the vertical direction Y. As shown in FIG. 15, the top surface and the bottom surface of each of the first stripe patterns 736 are respectively aligned with each of the first plane 732a of the first stepped surface 732 and each of the first planes 734a of the second stepped surface 734 as shown in FIG. 14, and the top surface and the bottom surface of each of the second stripe patterns 738 are respectively aligned with each of the second plane 732b of the first stepped surface 732 and each of the second planes 734b of the second stepped surface 734 as shown in FIG. 14. Accordingly, the first stripe patterns 736 and the second stripe patterns 738 are alternately arranged in the horizontal direction X.

Next, further in view of FIG. 13 and FIG. 15, the stripe patterns are trimmed into a trimming pattern (step S52). Precisely speaking, a width W1 of each of the first stripe patterns 736 and a width W2 of each of the second stripe patterns 738 in the horizontal direction X as shown in FIG. 15 are expanded, to form a plurality of first trimming patterns 740 and a plurality of second trimming patterns 742 as shown in FIG. 15, with each of the first trimming patterns 740 obtaining a relative greater width W3, and with each of the second trimming patterns 742 obtaining a relative greater width W4. Then, the width W3 of each first trimming pattern 740 is greater than the width W1 of each first stripe pattern 736, and the width W4 of each second trimming pattern 744 is greater than the width W2 of each second stripe pattern 738, such that, one of the first trimming patterns 740 may be partially overlapped with a corresponding one of the second trimming patterns 744 being adjacent thereto. In one embodiment, the width W1 of each first stripe pattern 736 is for example the same as the width W2 of each second stripe pattern 738, and the width W3 of each first trimming pattern 740 is also the same the width W4 of each second trimming pattern 742, as shown in FIG. 15, but not limited thereto. In another embodiment, the width W1 of each first stripe pattern 736 may be optionally greater than the width W2 of each second stripe pattern 738, or the width W3 of each first trimming pattern 740 may be optionally different from the width W4 of each second trimming pattern 742, after trimming the stripe patterns, so that, the first trimming patterns 740 will all achieving partially overlapping with the adjacent one of the second trimming patterns 742.

After that, as shown in FIG. 13, the trimming patterns are merged into a photomask pattern (step S53). The first trimming patterns 740 and the second trimming patterns 742 are merged into a merged photomask pattern (not shown in the drawings), and the merged photomask pattern is then outputted through the computer component, to form a mask layer on the target layer 110 as shown in FIG. 4 (step S6). Then, an etching process is performed through the mask layer to form another semiconductor structure (step S7).

Overall speaking, the photomask pattern with the stepped surface is processed by the computing system, for improving the misalignment issue, space-wasting issue or patterning incomplete issue possibly caused by various arrangements or various sizes among different layout patterns, so that, a mask being outputted substantially will obtain more precise patterns and profiles thereby. Thus, the mask will have improved quality and a semiconductor structure fabricated subsequently will therefore gain better reliability and performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a semiconductor structure, comprising:
providing a computing system;
inputting a plurality of first photomask patterns, the plurality of first photomask patterns being arranged into an array along a first direction and a second direction being not perpendicular to each other, and the array comprising a plurality of odd columns and a plurality of even columns arranged in a vertical direction;
inputting a second photomask pattern to completely overlay each one of a portion of the plurality of first photomask patterns, and to completely expose each one of another a portion of the plurality of first photomask patterns, wherein the second photomask pattern comprises a stepped surface in a horizontal direction;
sequentially outputting the plurality of first photomask patterns and the second photomask pattern, to respectively form a first mask layer and a second mask layer on a target layer; and
performing an etching process on the target layer through the first mask layer and the second mask layer, to form the semiconductor structure.

2. The method of fabricating the semiconductor structure according to claim 1, outputting the second photomask pattern further comprising:
decomposing the second photomask pattern, to form a plurality of sub-mask patterns being at least partially overlapped with each other; and
simultaneously outputting the plurality of sub-mask patterns, to form the second mask layer.

3. The method of fabricating the semiconductor structure according to claim 2, the plurality of sub-mask patterns further comprising:
a plurality of first sub-mask patterns extending in the vertical direction; and
a plurality of second sub-mask patterns extending in the vertical direction, the plurality of first sub-mask patterns and the plurality of second sub-mask patterns are alternately arranged in the horizontal direction.

4. The method of fabricating the semiconductor structure according to claim 3, wherein each of the plurality of first sub-mask patterns and each of the plurality of second sub-mask patterns respectively overlaps the plurality of first photomask patterns arranged in the plurality of odd columns and the plurality of first photomask patterns arranged the plurality of even columns.

5. The method of fabricating the semiconductor structure according to claim 2, the plurality of sub-mask patterns further comprising:
a first sub-mask pattern; and
a plurality of second sub-mask patterns sequentially arranged in the horizontal direction, wherein each of the second sub-mask patterns partially overlaps the first sub-mask pattern.

6. The method of fabricating the semiconductor structure according to claim 5, the first sub-mask pattern further comprises a plurality of protrusions being alternately arranged with the plurality of second sub-mask patterns in the horizontal direction.

7. The method of fabricating the semiconductor structure according to claim 5, the plurality of sub-mask patterns further comprising:
a plurality of third sub-mask patterns sequentially arranged in the horizontal direction, wherein the plurality of third sub-mask patterns and the plurality of second sub-mask patterns are alternately arranged in the horizontal direction and each partially overlaps with the first sub-mask pattern.

8. The method of fabricating the semiconductor structure according to claim 1, wherein the stepped surface comprises a plurality of first planes and a plurality of second planes being alternately arranged and being not coplanar with the plurality of first planes, and a pitch between two adjacent ones of the plurality of first photomask patterns is larger than a minimum distance from any one of the plurality of first planes or the plurality of second planes to a corresponding one of the plurality of first photomask patterns.

9. The method of fabricating the semiconductor structure according to claim 1,
forming a plurality of target patterns on the target layer through the first mask layer, the plurality of target patterns being arranged in the first direction and the second direction into an array; and
defining a target boundary on the target layer through the second mask layer, the target boundary comprising a first arc edge and a second arc edge being protruded toward the vertical direction, wherein a central point of the first arc edge and a central point of the second arc edge are not on a same plane in the horizontal direction.

10. The method of fabricating the semiconductor structure according to claim 1, outputting the second photomask pattern further comprising:
inputting a plurality of sub-mask patterns being partially overlapped with each other, the plurality of sub-mask patterns completely overlapping each one of a portion of the plurality of first photomask patterns; and
merging the plurality of sub-mask patterns into the second photomask pattern.

11. The method of fabricating the semiconductor structure according to claim 10, the plurality of sub-mask patterns further comprising:
a plurality of first sub-mask patterns extending in the vertical direction; and
a plurality of second sub-mask patterns extending in the vertical direction, the plurality of first sub-mask patterns and the plurality of second sub-mask patterns are alternately arranged in the horizontal direction, each of the plurality of first sub-mask patterns and each of the plurality of second sub-mask patterns respectively overlaps the plurality of first photomask patterns arranged in the plurality of odd columns and the plurality of first photomask patterns arranged the plurality of even columns.

12. The method of fabricating the semiconductor structure according to claim 10, the plurality of sub-mask patterns further comprising:
a first sub-mask pattern; and
a plurality of second sub-mask patterns sequentially arranged in the horizontal direction, wherein each of the second sub-mask patterns partially overlaps the first sub-mask pattern, and the first sub-mask pattern further comprises a plurality of protrusions being alternately arranged with the second sub-mask patterns in the horizontal direction.

13. The method of fabricating the semiconductor structure according to claim 10, the plurality of sub-mask patterns further comprising:
a first sub-mask pattern;
a plurality of second sub-mask patterns sequentially arranged in the horizontal direction, wherein each of the second sub-mask patterns partially overlaps the first sub-mask pattern; and
a plurality of third sub-mask patterns sequentially arranged in the horizontal direction, wherein the plurality of third sub-mask patterns and the plurality of second sub-mask patterns are alternately arranged in the horizontal direction.

14. A method of fabricating a semiconductor structure, comprising:
providing a computing system;
inputting a photomask pattern, the photomask pattern comprising a first stepped surface and a second stepped surface respectively at two opposite sides thereof in the vertical direction;
performing a decompose process on the photomask pattern, decomposing the photomask pattern into a plurality of first stripe patterns and a plurality of second stripe patterns alternately arranged in a horizontal direction being perpendicular to the vertical direction;
performing a trimming process on the plurality of first stripe patterns and the plurality of second stripe patterns, expanding a width of each of the plurality of first stripe patterns and a width of each of the plurality of second stripe patterns in the horizontal direction, to form a plurality of first trimming patters and a plurality of second trimming patterns, wherein each of the plurality of first trimming patters overlaps an adjacent one of the plurality of second trimming patterns;
merging the plurality of first trimming patters and the plurality of second trimming patterns, to form a merged photomask pattern;
outputting the merged photomask pattern, to form a mask layer on a target layer; and
performing an etching process on the target layer through the mask layer, to from the semiconductor structure.

15. The method of fabricating a semiconductor structure according to claim 14, wherein the width of each of the plurality of first stripe patterns is the same as the width of each of the plurality of second stripe patterns.

16. The method of fabricating a semiconductor structure according to claim 14, wherein the width of each of the plurality of first stripe patterns is larger than the width of each of the plurality of second stripe patterns.

17. A semiconductor structure, comprising:
a substrate; and
a target layer disposed on the substrate, comprising a target boundary and a plurality of target patterns;
wherein the plurality of target patterns is disposed within the target boundary, the plurality of target patterns are arranged in a first direction and a second direction into an array, and comprises a plurality of odd columns and a plurality of even columns in a vertical direction, the target boundary comprises a first arc edge and a second arc edge being protruded toward the vertical direction, and a central point of the first arc edge and a central point of the second arc edge are not on a same plane in a horizontal direction.

18. The semiconductor structure according to claim 17, wherein a pitch between any two adjacent ones of the plurality of parget patterns is the same with each other, and a minimum distance from the central point of the first arc edge to a corresponding one of the plurality of target patterns arranged in the plurality of odd columns is less than the pitch.

19. The semiconductor structure according to claim 18, wherein a minimum distance from the central point of the second arc edge to a corresponding one of the plurality of target patterns arranged in the plurality of even columns is less than the pitch.

20. The semiconductor structure according to claim 17, wherein the target layer comprises a dielectric material and a conductive material.
